(19) United States
(12) Patent Application Publication
(10) Pub. No.: US 2015/0144961 A1
(43) Pub. Date: May 28, 2015

(54) HIGH FREQUENCY DEVICE AND METHOD OF MANUFACTURING THE SAME

(71) Applicant: Electronics and Telecommunications Research Institute, Daejeon (KR)

(72) Inventors: Hyung Sup YOON, Daejeon (KR); Byoung Gue MIN, Sejong (KR); Ho Kyun AHN, Daejeon (KR); Jong Won LIM, Daejeon (KR); Dong Min KANG, Daejeon (KR); Jong Min LEE, Daejeon (KR)

(73) Assignee: Electronics and Telecommunications Research Institute, Daejeon (KR)

(21) Appl. No.: 14/175,452

(22) Filed: Feb. 7, 2014

(30) Foreign Application Priority Data
Nov. 26, 2013 (KR) 10-2013-0144810

(51) Int. Cl. H01L 29/778; H01L 29/45; H01L 29/66

(52) U.S. Cl. CPC H01L 29/7787; H01L 29/66431; H01L 29/452
USPC 257/77; 438/605

(57) ABSTRACT

A high frequency device includes: a capping layer formed on an epitaxial structure; source and drain electrodes formed on the capping layer; a multilayer insulating pattern formed on entire surfaces of the source and drain electrodes and the capping layer in a step shape; a T-shaped gate passing through the multilayer insulating pattern and the capping layer to be in contact with the epitaxial structure; and a passivation layer formed along entire surfaces of the T-shaped gate and the multilayer insulating pattern.

### CROSS-REFERENCE TO RELATED APPLICATION

This application is based on and claims priority from Korean Patent Application No. 10-2013-0144810, filed on Nov. 26, 2013, with the Korean Intellectual Property Office, the disclosure of which is incorporated herein in its entirety by reference.

### BACKGROUND

1. Field

The present invention relates to an electronic device, and a method of manufacturing the same, and more particularly, to a high frequency device and a method of manufacturing the same.

2. Discussion of Related Art

A high frequency device is a device capable of high-speed processing a high frequency band signal, and for example, a High Electron Mobility Transistor (HEMT) and a Metal-Semiconductor Field Effect Transistor (MESFET) are used as the high frequency device.

Hereinafter, a manufacturing method and a structure of a high frequency device in the related art will be described with reference to FIGS. 1A to 1C.

As illustrated in FIG. 1A, a buffer layer 12, a channel layer 13, a spacer layer 14, and a Schottky layer 15 are sequentially formed on a substrate 11. Next, source and drain electrodes 16 are formed on the Schottky layer 15, and then a silicon nitride layer 17 is formed. Subsequently, a trench T through which the Schottky layer 15 is exposed is formed by etching the silicon nitride layer 17.

As illustrated in FIG. 1B, a conductive layer is formed on the silicon nitride layer 17 so as to fill the trench T, and then a T-shaped gate 18 is formed by etching the conductive layer.

As illustrated in FIG. 1C, the silicon nitride layer 19 is formed along surfaces of the T-shaped gate 18 and the silicon nitride layer 17.

According to the aforementioned related art, the T-shaped gate 18 is formed on the thick silicon nitride layer 17, and the T-shaped gate 18 is in direct contact with the silicon nitride layer 17. Here, since the silicon nitride layer 17 is a material having a relatively high dielectric constant, so that high parasitic capacitance is generated between the T-shaped gate 18 and the source and drain electrodes 16. Accordingly, a problem of deterioration of a high frequency characteristic is caused. Further, the conductive layer is not uniformly deposited within the trench having a narrow width, so that it is difficult to form the T-shaped gate 18. Further, a high electric field is generated between the T-shaped gate 18 and the source and drain electrodes 16, so that there may be a problem in that a breakdown voltage of the high frequency device is decreased and reliability of the device deteriorates.

### SUMMARY

The present invention has been made in an effort to provide a high frequency device with an improved high frequency characteristic and improved reliability, and a method of manufacturing a high frequency device having an easy manufacturing process.

An embodiment of the present invention provides a high frequency device, including: a capping layer formed on an epitaxial structure; source and drain electrodes formed on the capping layer; a multilayer insulating pattern formed on entire surfaces of the source and drain electrodes and the capping layer in a step shape; a T-shaped gate passing through the multilayer insulating pattern and the capping layer to be in contact with the epitaxial structure; and a passivation layer formed along entire surfaces of the T-shaped gate and the multilayer insulating pattern.

Another embodiment of the present invention provides a method of manufacturing a high frequency device, including: forming a capping layer on an epitaxial structure; forming a source electrode and a drain electrode on the capping layer; forming a multilayer insulating pattern along entire surfaces of the source and drain electrodes and the capping layer in a step shape; forming a T-shaped gate passing through the capping layer and the multilayer insulating pattern to be in contact with the epitaxial structure; and forming a passivation layer formed along entire surfaces of the T-shaped gate and the multilayer insulating pattern.

According to the embodiment of the present invention, it is possible to manufacture a field effect type high frequency device by decreasing parasitic capacitance between a T-shaped gate and source and drain electrodes, and releasing an electric field generated between the T-shaped gate and source and the drain electrodes. Further, it is possible to improve reliability of the high frequency device.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A to 1C are cross-sectional views illustrating a method of manufacturing a high frequency device in the related art; and

FIGS. 2A to 2F are cross-sectional views illustrating a method of manufacturing a high frequency device according to an exemplary embodiment of the present invention.

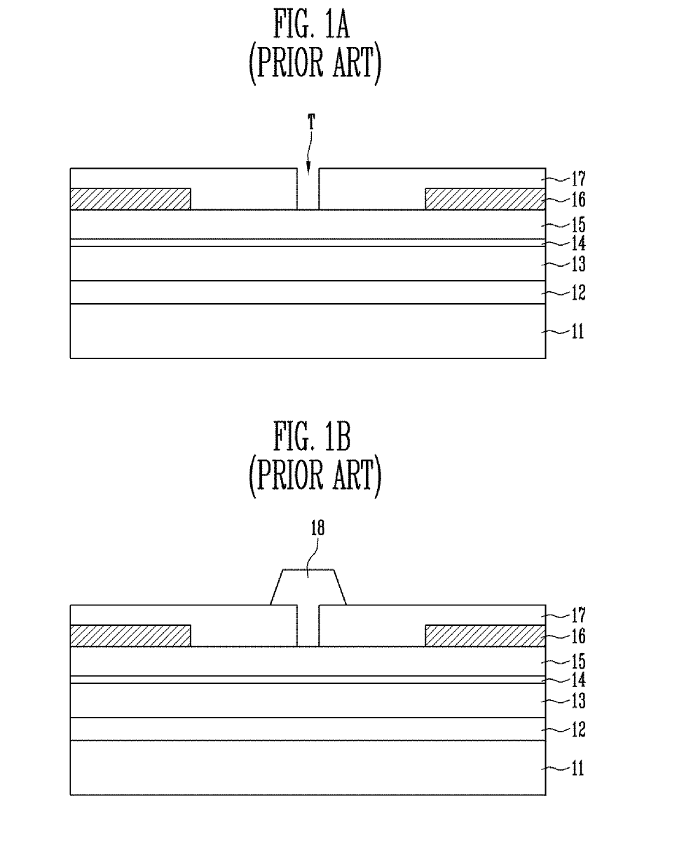

### DETAILED DESCRIPTION

Hereinafter, an exemplary embodiment of the present invention will be described. In the drawings, the thicknesses and the intervals of elements are exaggerated for convenience of illustration, and may be exaggerated compared to an actual physical thickness. In describing the present invention, a publicly known configuration irrelevant to the principal point of the present invention may be omitted. It should note that in giving reference numerals to elements of each drawing, like reference numerals refer to like elements even though like elements are shown in different drawings.

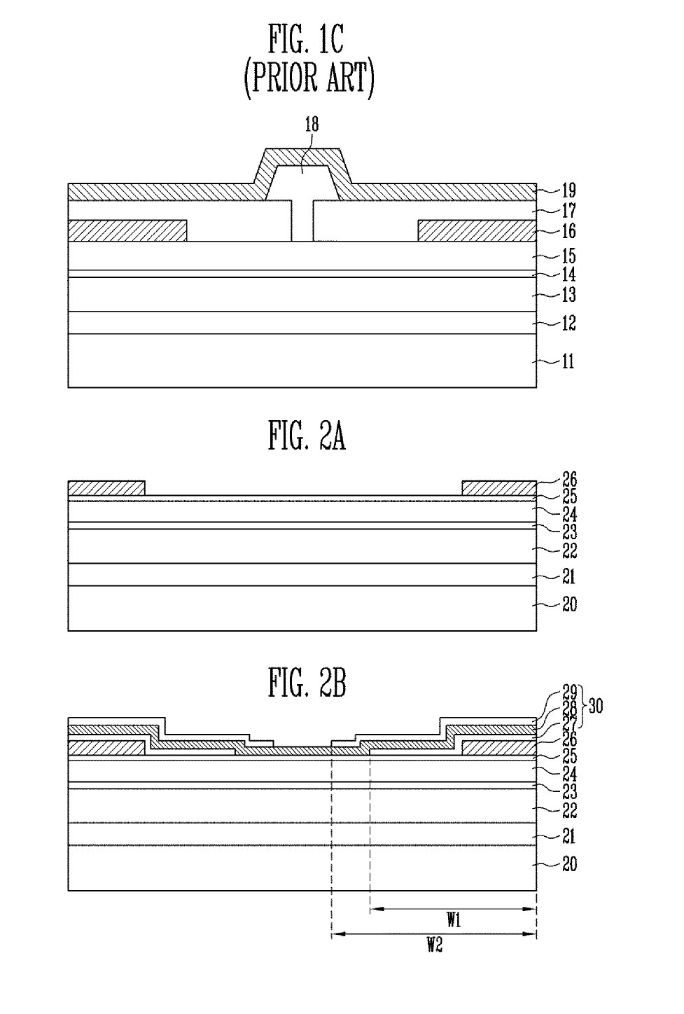

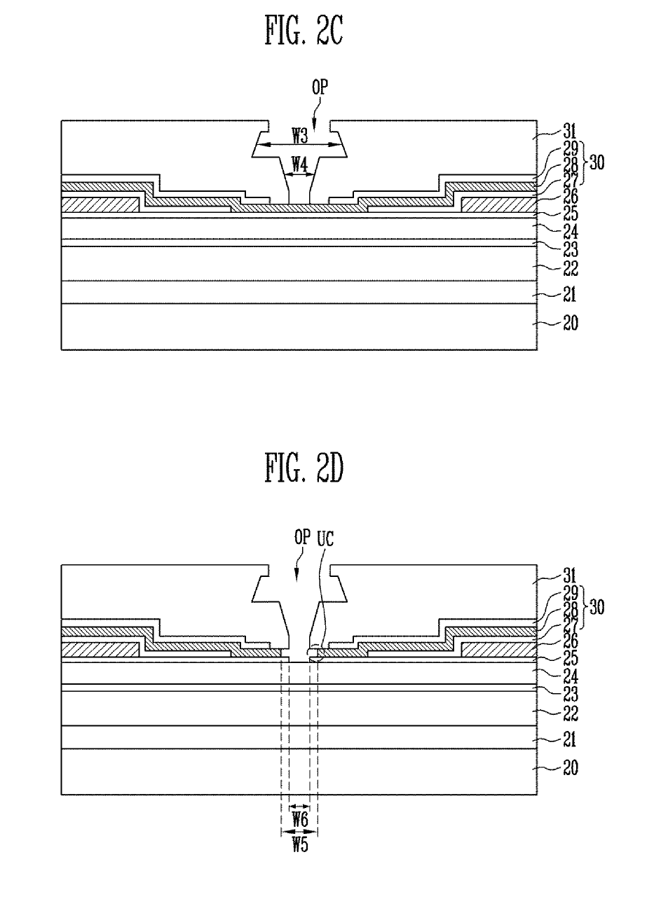

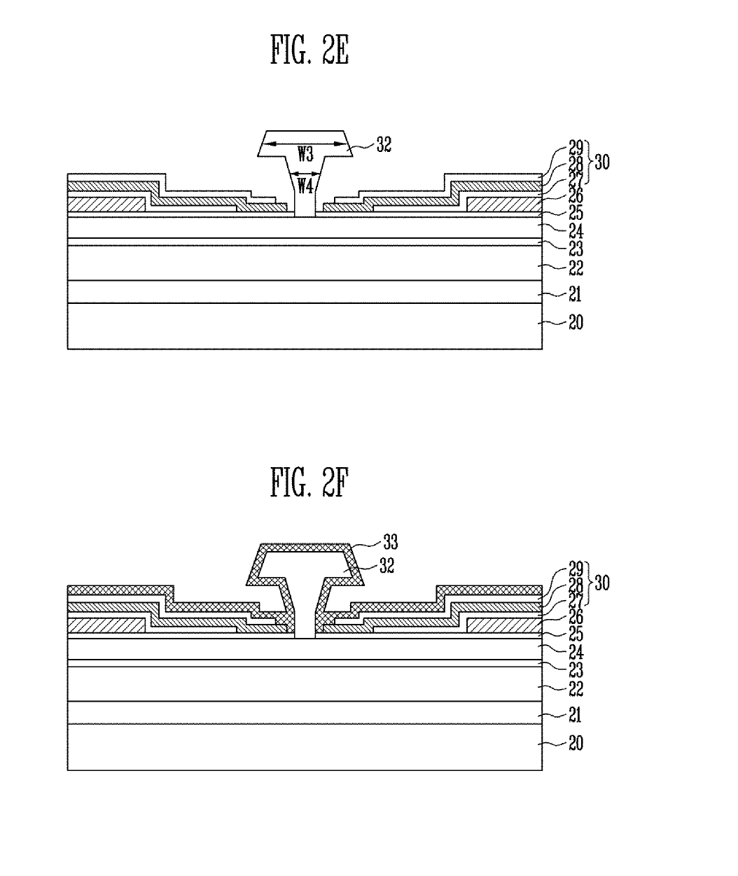

FIGS. 2A to 2F are cross-sectional views illustrating a method of manufacturing a high frequency device according to an exemplary embodiment of the present invention.

As illustrated in FIG. 2A, an epitaxial structure is formed. For example, the epitaxial structure includes a substrate 20, and a buffer layer 21, a channel layer 22, a spacer layer 23, a Schottky layer 24, and a capping layer 25 sequentially stacked on the substrate 20. Here, the substrate 20 may be an SiC substrate. Further, the buffer layer 21 may include AlN, the channel layer 22 may include undoped GaN, the Schottky layer 23 may include undoped AlGaN, and the capping layer 24 may include undoped GaN.

Next, source and drain electrodes 26 are formed on the capping layer 25. Here, the source electrode and the drain electrodes are formed to be spaced apart from each other by a predetermined distance, and the capping layer 25 is exposed between the source electrode and the drain electrode. For example, an active region is defined by injecting ions into the epitaxial structure, and the source and drain electrodes 26 may be formed by forming an ohmic metal by using a vacuum depositing device and then performing a heat treatment process. The ohmic metal may include at least one of lead (Pd), titanium (Ti), aluminum (Al), molybdenum (Mo), and gold (Au). Further, the heat treatment process may be performed at a temperature of 800 to 850° C.

As illustrated in FIG. 2B, a step-shaped multilayer insulating pattern 30 is formed on the capping layer 25 on which the source and drain electrodes 26 are formed. The multilayer insulating pattern 30 is formed in a step shape along an entire surface of the source and drain electrodes 26 and the capping layer 25. Here, the multilayer insulating pattern 30 may include a first oxide layer 27, a nitride layer 28, and a second oxide layer 29 which are sequentially stacked.

A method of forming the multilayer insulating pattern 30 according to the exemplary embodiment of the present invention will be described below. First, the first oxide layer 27 is formed along the entire surface of the source and drain electrodes 26 and the capping layer 25. For example, the first oxide layer 27 having a thickness of 250 to 300 is formed by Plasma Enhanced Chemical Vapor Deposition (PECVD). The first oxide layer 27 may include a silicon oxide layer (SiO²). Next, a photoresist pattern (not shown) is formed on the first oxide layer 27, and the first oxide layer is dry-etched by using the photoresist pattern as an etching barrier. Accordingly, the first oxide layer 27 having a first width W1 covering the source and drain electrodes 26 and a part of the capping layer 25 is formed.

Next, the nitride layer 28 is formed along the entire surface of the first oxide layer 27 and the capping layer 25. For example, the nitride layer 28 with a thickness of 450 to 550 is formed at a temperature of 250 to 350 using the PECVD scheme. Here, a height of the first oxide layer 27 formed at a lower side is transferred to a surface of the nitride layer 28 as it is, and the nitride layer 28 has a step on the surface thereof.

Next, a second oxide layer 29 is formed on the nitride layer 28. For example, the oxide layer 29 with a thickness of 250 to 350 is formed at a temperature of 240 to 280. Here, the second oxide layer 29 is formed along a surface of the nitride layer 28, so that the second oxide layer 29 also has a step on the surface thereof.

Next, the second oxide layer 29 is patterned. For example, a photoresist pattern (not shown) is formed on the second oxide layer 29. Here, the photoresist pattern is formed so as to cover the source and drain electrodes 26 and the first oxide layer 27, and have a wider width than that of the first oxide layer 27. Next, the second oxide layer 29 is dry-etched using an electron beam lithography scheme. Accordingly, the second oxide layer 29 having a second width W2 covering the source and drain electrodes 26 and the first oxide layer 27, and a part of the nitride layer is formed. Here, the second width W2 has a larger value than that of the first width W1.

Accordingly, the multilayer insulating pattern 30 including the first oxide layer 27, the nitride layer 28, and the second oxide layer 29 having various widths are formed. As described above, it is possible to easily form the step-shaped multiplayer insulating pattern 30 by patterning the first oxide layer 27, the nitride layer 28, and the second oxide layer 29 with various widths.

As illustrated in FIG. 2C, a mold pattern 31 having a T-shaped opening OP is formed on the multilayer insulating pattern 30. Here, the T-shaped opening is positioned between the source electrode and the drain electrode, and is formed so as to expose the multilayer insulating pattern 30, for example, the nitride layer 28. For example, a photoresist layer, in which a first photoresist layer including polymethylmethacrylate (PMMA) and having a thickness of 4,500 to 5,500, a second photoresist layer including co-polymer and having a thickness of 7,500 to 8,500, and a third photoresist layer including PMMA and having a thickness of 2,500 to 3,500 are sequentially stacked, is formed. Next, the T-shaped opening OP having a head portion with a third width W3 and a tail portion with a fourth width W4 is formed by first etching the photoresist layer using the electron beam lithography scheme. Here, the tail portion is connected to a lower portion of the head portion, and the third width W3 has a larger value than that of the fourth width W4. Here, a width of an upper portion of the tail portion is increased by second etching the photoresist layer by using oxygen plasma. Accordingly, it is possible to easily form the T-shaped opening OP by forming the photoresist by combining the PMMA and the co-polymer. Further, it is possible to easily increase the width of the upper portion of the tail portion.

As illustrated in FIG. 2D, the epitaxial structure is exposed by etching the multilayer insulating pattern 30 and the capping layer 25 through the T-shaped opening. For example, a undercut UC connected with the T-shaped opening OP is formed by isotropic-etching the nitride layer 28 using an Inductively Coupled Plasma (ICP) scheme at an SF₆ atmosphere. Next, the Schottky layer 24 is exposed by dry-etching the capping layer 25 by the ICP scheme at BCl₃ and Cl₂ atmospheres. Accordingly, the T-shaped opening OP is expanded toward a lower side so as to pass through the nitride layer 28 and the capping layer 25. Further, the T-shaped opening OP has a fifth width W5 in a region in which the T-shaped opening OP passes through the nitride layer 27, and has a sixth width W in a region in which the T-shaped opening OP passes through the capping layer 25. The fifth width W5 has a larger value than that of the sixth width W6.

As illustrated in FIG. 2E, a T-shaped gate 32 is formed within the T-shaped opening OP, and then the mold pattern 31 is removed. For example, a first conductive layer including lead (Pd), a second conductive layer including titanium (Ti), a third conductive layer including platinum (Pt), and a fourth conductive layer including gold (Au) are sequentially formed within the T-shaped opening OP using the vacuum deposition scheme. In this case, since the width of the tail portion of the T-shaped opening OP becomes large as gets closer to the upper portion, it is possible to easily deposit the conductive layer within the T-shaped opening OP. Accordingly, the T-shaped gate 32 having the head portion with the third width W3 and the tail portion width the fourth width W4 is formed.

For reference, the undercut UC formed by etching the nitride layer 27 has a fine width, so that the conductive layer is not deposited within the undercut UC. Accordingly, the T-shaped gate 32 is not in contact with the nitride layer 28.

As illustrated in FIG. 2F, a passivation layer 33 is formed along the entire surface of the T-shaped gate 32 and the silicon nitride layer 30. Here, the passivation layer 33 may be formed by filling the undercut UC. For example, the passivation layer 33 including an aluminum oxide layer (Al₂O₃) may be formed using an Atomic Layer Deposition (ALD) scheme.

According to the aforementioned process, it is possible to manufacture a field effect high frequency device, such as a gallium nitride High Electron Mobility Transistor (GaN HEMT) and a Metal-Semiconductor Field Effect Transistor (MESFET). Here, the multilayer insulating pattern 30 has a structure in which the oxide layer and the nitride layer are alternately stacked, so that it is possible to decrease a thickness of the nitride layer interposed between the T-shaped gate 32 and the source and drain electrodes 26 compared to the related art. Accordingly, it is possible to decrease parasitic capacitance between the T-shaped gate 32 and the source and drain electrodes 26. Further, it is possible to manufacture a field effect high frequency device having a high breakdown voltage by releasing an electric field generated between the T-shaped gate 32 and the source and drain electrodes 26.

As described above, the embodiment has been disclosed in the drawings and the specification. The specific terms used herein are for purposes of illustration, and do not limit the scope of the present invention defined in the claims. Accordingly, those skilled in the art will appreciate that various modifications and another equivalent example may be made without departing from the scope and spirit of the present disclosure. Therefore, the sole technical protection scope of the present invention will be defined by the technical spirit of the accompanying claims.

What is claimed is:

1. A high frequency device, comprising:
a capping layer formed on an epitaxial structure;
source and drain electrodes formed on the capping layer;
a multilayer insulating pattern formed on entire surfaces of the source and drain electrodes and the capping layer in a step shape;
a T-shaped gate passing through the multilayer insulating pattern and the capping layer to be in contact with the epitaxial structure; and
a passivation layer formed along entire surfaces of the T-shaped gate and the multilayer insulating pattern.

2. The high frequency device of claim 1, wherein the T-shaped gate has a head portion and a tail portion connected with the head portion and having a narrower width than that of the head portion, and the width of the tail portion becomes narrow as becoming closer to a lower portion.

3. The high frequency device of claim 1, wherein the epitaxial structure includes a substrate, and a buffer layer, a channel layer, and a Schottky layer sequentially stacked on the substrate.

4. The high frequency device of claim 3, wherein the substrate is an SiC substrate, the buffer layer includes AlN, the channel layer includes undoped GaN, the Schottky layer includes undoped AlGaN, the capping layer includes undoped GaN, and the source and drain electrodes include ohmic metal.

5. The high frequency device of claim 1, wherein the multilayer insulating pattern includes a first oxide layer, a nitride layer, and a second oxide layer which are sequentially stacked.

6. The high frequency device of claim 1, wherein the passivation layer includes an aluminum oxide layer Al₂O₃.

7. A method of manufacturing a high frequency device, comprising:
forming a capping layer on an epitaxial structure;
forming a source electrode and a drain electrode on the capping layer;
forming a multilayer insulating pattern along entire surfaces of the source and drain electrodes and the capping layer in a step shape;
forming a T-shaped gate passing through the capping layer and the multilayer insulating pattern to be in contact with the epitaxial structure; and
forming a passivation layer formed along entire surfaces of the T-shaped gate and the multilayer insulating pattern.

8. The method of claim 7, wherein the forming of the multilayer insulating pattern includes:
forming a first oxide layer covering the source and drain electrodes and a part of the capping layer;
forming a nitride layer along entire surfaces of the capping layer and the first oxide layer;
forming a second oxide layer along an entire surface of the nitride layer; and
etching a part of the second oxide layer so that the nitride layer is exposed.

9. The method of claim 7, wherein the forming of the T-shaped gate includes:
forming a mold pattern having a T-shaped opening on the multilayer insulating pattern;
etching the multilayer insulating pattern and the capping layer through the T-shaped opening so that the epitaxial structure is exposed; and
forming the T-shaped gate within the T-shaped opening.

10. The method of claim 9, wherein the forming of the mold pattern includes:
forming a photoresist layer on the multilayer insulating pattern;
forming the T-shaped opening, which has a head portion and a tail portion connected with the head portion and having a narrower width than that of the head portion by etching the photoresist layer by using an electron beam lithography scheme; and
isotropic-etching the photoresist layer using an oxygen plasma scheme so as to increase a width of an upper portion of the tail portion.

11. The method of claim 10, wherein the forming of the photoresist layer includes:
forming a first photoresist layer including polymethylmethacrylate (PMMA);
forming a second photoresist layer including co-polymer on the first photoresist layer; and
forming a third photoresist layer including PMMA on the second photoresist layer.

12. The method of claim 9, wherein the etching of the multilayer insulating pattern and the capping layer includes:
forming an undercut connected with the T-shaped opening by isotropic-etching the multilayer insulating pattern using an Inductively Coupled Plasma (ICP) scheme at an SF₆ atmosphere; and
dry-etching the capping layer using the ICP schene at BC1₃ and C1₂ atmospheres.

13. The method of claim 9, wherein the forming of the T-shaped gate includes:
sequentially forming a first conductive layer including lead (Pd), a second conductive layer including titanium (Ti), a third conductive layer including platinum (Pt), and a fourth conductive layer including gold (Au).

14. The method of claim 9, further comprising:
removing the mold pattern after forming the T-shaped gate.

15. The method of claim 7, wherein the forming of the passivation layer includes forming the passivation layer including an aluminum oxide layer Al₂O₃ using an Atomic Layer Deposition (ALD) scheme.
